(19) United States
(12) Patent Application Publication
(10) Pub. No.: US 2024/0227100 A1
(43) Pub. Date: Jul. 11, 2024

(54) JIG FOR BEING INTEGRATED WITH INGOT

(71) Applicant: DISCO CORPORATION, Tokyo (JP)

(72) Inventors: Naoki OMIYA, Tokyo (JP); Kazuki MORI, Tokyo (JP)

(21) Appl. No.: 18/405,135

(22) Filed: Jan. 5, 2024

(30) Foreign Application Priority Data
Jan. 11, 2023 (JP) 2023-002403

(51) Int. Cl. B23Q 3/08

(52) U.S. Cl. CPC B23Q 3/084

(57) ABSTRACT

A jig for use in manufacturing a wafer from an ingot and for being delivered while being integrated with the ingot includes a base having a holding mechanism for holding the ingot such that the ingot protrudes therefrom and an information recording member fixed to the base for recording individual information of the ingot identifiably therein. Preferably, the base has a disk-shaped recess defined therein that has a predetermined depth for accommodating a bottom portion of the ingot therein.

### BACKGROUND OF THE INVENTION

### Field of the Invention

The present invention relates to a jig for use in manufacturing a plurality of wafers from an ingot and for being delivered while being integrated with the ingot and a method of manufacturing a plurality of wafers from each of a plurality of ingot units each including an ingot and a jig that are integrated with each other.

### Description of the Related Art

In order to manufacture a plurality of wafers from a monocrystalline ingot of silicon (hereinafter referred to as “Si ingot”), the Si ingot is cut by a wire saw, for example (see, for example, JP 2000-94221A). Manufacturing a plurality of wafers from a monocrystalline ingot of silicon carbide (hereinafter referred to as “SiC ingot”) by cutting the SiC ingot with a wire saw takes more time because the SiC ingot is harder than the Si ingot.

There has been proposed in the art a technology for forming a fragile peel-off layer in an SiC ingot at a predetermined depth from an end face of the SiC ingot with a laser beam whose wavelength is transmittable through the SiC ingot, rather than a wire saw, and peeling off an SiC wafer from the SiC ingot along the peel-off layer (see, for example, JP 2016-111143A). Specifically, while a focused spot of the laser beam is positioned in the SiC ingot at a predetermined depth, which corresponds to a thickness of a monocrystalline wafer of silicon carbide (hereinafter referred to as “SiC wafer”), from the end face of the SiC ingot, the focused spot and the SiC ingot are moved relatively to each other, forming the peel-off layer in the SiC ingot.

To increase the number of SiC wafers that can be manufactured per unit time, it is required to process a plurality of SiC ingots concurrently for manufacturing SiC wafers therefrom. Specifically, a laser processing apparatus for forming peel-off layers in an SiC ingot, a printing apparatus for printing identification information on an upper surface of an SiC ingot, a peeling apparatus for peeling off SiC wafers from an SiC ingot, and a grinding apparatus for grinding the upper surface of an SiC ingot to planarize the upper surface are simultaneously actuated to process respective SiC ingots concurrently. For processing the SiC ingots concurrently, an operator delivers the SiC ingots to these apparatuses and operates the apparatuses, for example.

More specifically, while the laser processing apparatus is processing a first SiC ingot, the printing apparatus processes a second SiC ingot, the peeling apparatus processes a third SiC ingot, and the grinding apparatus processes a fourth SiC ingot. Thereafter, the operator delivers the fourth SiC ingot to the laser processing apparatus, delivers the first SiC ingot to the printing apparatus, delivers the second SiC ingot to the peeling apparatus, and delivers the third SiC ingot to the grinding apparatus. Then, while the laser processing apparatus is processing the fourth SiC ingot, the printing apparatus processes the first SiC ingot, the peeling apparatus processes the second SiC ingot, and the grinding apparatus processes the third SiC ingot.

By thus moving the SiC ingots from one apparatus to another and processing them successively on the apparatuses, nearly 100 SiC wafers each having a thickness of approximately 0.4 mm are manufactured from each of the SiC ingots that has a thickness of approximately 40 mm, for example. Under such circumstances, however, it may become difficult to identify the individual SiC ingots, giving rise to the problems that the SiC ingots may be processed under wrong processing conditions and wrong manufacturing histories may be recorded for the SiC ingots.

The same problems can also occur in the manufacture of wafers from various hard monocrystalline ingots including a monocrystalline ingot of gallium nitride (hereinafter referred to as “GaN ingot”), a monocrystalline ingot of lithium tantalate (hereinafter referred to as “LT ingot”), a monocrystalline ingot of lithium niobate (hereinafter referred to as “LN ingot”), and a monocrystalline ingot of synthetic diamond (hereinafter referred to as “synthetic diamond ingot”).

### SUMMARY OF THE INVENTION

The present invention has been made in view of the above problems. It is an object of the present invention to make it easy to identify and manage individual ingots to be delivered, processed, or otherwise handled.

In accordance with an aspect of the present invention, there is provided a jig for use in manufacturing a wafer from an ingot and for being delivered while being integrated with the ingot, including a base having a holding mechanism for holding the ingot such that the ingot protrudes therefrom and an information recording member fixed to the base for recording individual information of the ingot identifiably therein.

Preferably, the base has a disk-shaped recess defined therein that has a predetermined depth for accommodating a bottom portion of the ingot therein.

Preferably, the base includes a central body capable of transmitting ultraviolet rays therethrough from a holding surface thereof as a bottom surface of the recess to a bottom surface of the base opposite the recess thicknesswise across the base, the holding mechanism includes an adhesive layer disposed on the holding surface and made of an ultraviolet-curable resin having bonding power that is lowered when irradiated with ultraviolet rays, and the ingot is held on the holding surface with the adhesive layer interposed therebetween before the adhesive layer is irradiated with ultraviolet rays.

Preferably, the adhesive layer disposed on the holding surface has a thickness smaller than the predetermined depth of the recess.

Preferably, the information recording member includes a plate capable of indicating on a surface thereof information represented by one or more combined of colors, symbols, numerals, letters, figures, patterns, pictures, and two-dimensional codes.

Preferably, the information recording member includes an integrated circuit (IC) tag for recording individual information that can be read or written via wireless communication.

Preferably, the IC tag is capable of recording information with respect to manufacture of the wafer in addition to the individual information.

In accordance with another aspect of the present invention, there is provided a method of manufacturing a plurality of wafers from each of a plurality of ingot units each including an ingot and a jig that are integrated with each other, the jig including a base having a holding mechanism for holding the ingot such that the ingot protrudes therefrom and an information recording member fixed to the base for recording individual information of the ingot identifiably therein, the method including a peel-off layer forming step of delivering an ingot unit to a laser processing apparatus and processing the ingot of the ingot unit with a laser beam on the laser processing apparatus to form a peel-off layer at a predetermined depth in the ingot as peeling initiating points along which a wafer is to be peeled off from the ingot, a peeling step of delivering the ingot unit with the peel-off layer formed in the ingot to a peeling apparatus and peeling off the wafer from the ingot along the peel-off layer, and a grinding step of delivering the ingot unit from which the wafer has been peeled off to a grinding apparatus and grinding an upper surface of the ingot of the ingot unit on the grinding apparatus, in which each of the ingot units is delivered successively to the laser processing apparatus, the peeling apparatus, and the grinding apparatus to circulate therethrough such that peel-off layer forming step, peeling step, and grinding step are successively performed on each of the ingot units, manufacturing a plurality of wafers from each of the respective ingots of the ingot units.

The jig according to the aspect of the present invention includes the base having the holding mechanism for holding the ingot such that the ingot protrudes therefrom and the information recording member fixed to the base for recording individual information of the ingot identifiably therein. Since the individual information of the ingots can be identified from the information recording members, the ingots can be easily identified and managed individually for increased productivity for wafers.

In the method of manufacturing a plurality of wafers according to the other aspect of the present invention, each of the ingot units that includes the ingot and the jig are integrated with each other is delivered successively to the laser processing apparatus, the peeling apparatus, and the grinding apparatus to circulate therethrough such that the peel-off layer forming step, the peeling step, and the grinding step are successively performed on each of the ingot units. When the ingots are thus processed in the peel-off layer forming step, the peeling step, and the grinding step, since the individual information of the ingots can be identified from the information recording members, the ingots can be easily identified and managed individually for increased productivity for wafers.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view of an ingot and a jig according to a first embodiment of the present invention;

FIG. 1B is a perspective view of an ingot unit including the ingot and the jig illustrated in FIG. 1A that are integrated with each other;

FIG. 2 is a cross-sectional view taken along line A-A of FIG. 1B;

FIG. 3 is a flowchart of a method of manufacturing a plurality of wafers from an ingot;

FIG. 4 is a perspective view of a laser processing apparatus;

FIG. 5 is a perspective view illustrating a peel-off layer forming step;

FIG. 6A is a side-elevational view, partly in cross section, of a peeling apparatus;

FIG. 6B is a side-elevational view, partly in cross section, illustrating a peeling step;

FIG. 7 is a perspective view illustrating a wafer that has been peeled off from an ingot in the peeling step;

FIG. 8 is a perspective view illustrating a grinding step;

FIG. 9A is a view illustrating a time sequence of the peel-off layer forming step performed on the laser processing apparatus;

FIG. 9B is a view illustrating a time sequence of the peeling step performed on the peeling apparatus;

FIG. 9C is a view illustrating a time sequence of the grinding step performed on a grinding apparatus;

FIG. 10 is a perspective view of an ingot unit according to a second embodiment of the present invention; and

FIG. 11 is a side-elevational view, partly in cross section, of an ingot unit according to a third embodiment of the present invention.

### DETAILED DESCRIPTION OF THE PREFERRED EMBODIMENTS

### First Embodiment

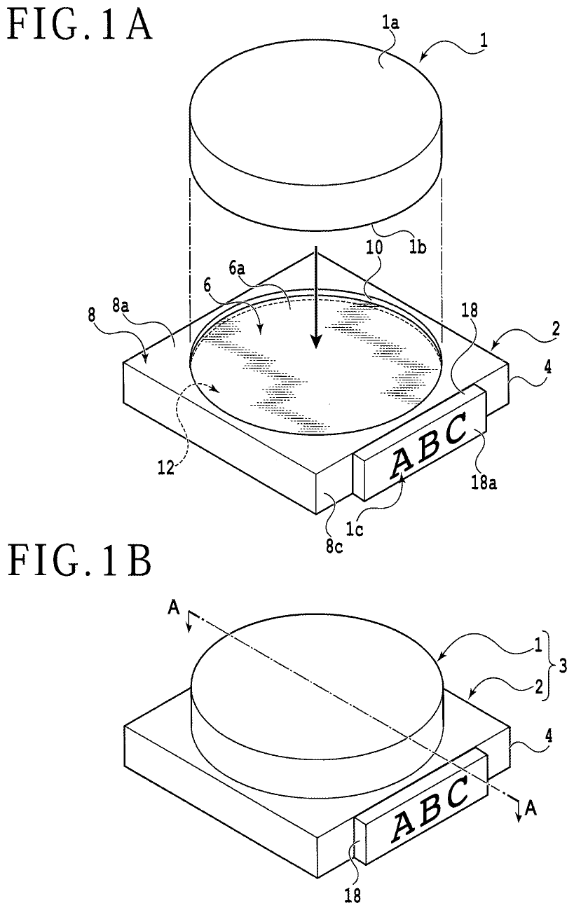

A first embodiment of the present invention will be described below with reference to FIGS. 1 through 9C of the accompanying drawings. FIG. 1A illustrates, in perspective, an ingot 1 and a jig 2 according to the first embodiment, and FIG. 1B illustrates, in perspective, an ingot unit 3 including the ingot 1 and the jig 2 that are integrated with each other. The ingot 1 is a monocrystalline Si ingot that has a substantially cylindrical shape, for example. The ingot 1 has a diameter ranging from approximately 50 mm (50±0.38 mm, i.e., 2 inches, according to the Semiconductor Equipment and Materials International (SEMI) standards) to approximately 300 mm (300±0.2 mm, i.e., 12 inches, according to the SEMI standards).

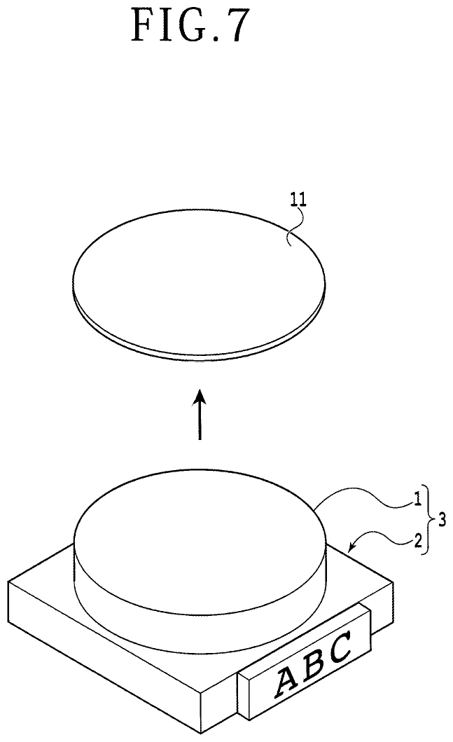

The ingot 1 has a thickness predetermined depending on the diameter thereof. For example, before a wafer 11 (see FIG. 7, etc.) is peeled off from the ingot 1, the ingot 1 has an initial thickness larger than 0.4 mm and smaller than 100 mm. The ingot 1 is not limited to an Si ingot, and may be an SiC ingot, a GaN ingot, an LT ingot, an LN ingot, or a synthetic diamond ingot, for example, as described above. The diameter and thickness of each of the ingots may be appropriately varied depending on its material.

The ingot 1 according to the present embodiment has a top surface 1a and a bottom surface 1b that are circular in shape. The ingot 1 may have an orientation flat defined in a cylindrical side surface thereof as a flat surface that lies perpendicularly to the top surface 1a and the bottom surface 1b. The orientation flat represents the crystal orientation of the ingot 1. Alternatively, the ingot 1 may have a notch, instead of the orientation flat, defined in the cylindrical side surface thereof. The ingot 1 is held on a base 4 of the jig 2.

The base 4 is made in its entirety of a material capable of transmitting therethrough light in a wavelength band ranging from 100 nm to 400 nm, i.e., ultraviolet rays typically having a wavelength such as 254 nm or 365 nm, for example. Specifically, the base 4 may be made of a material such as polymethyl methacrylate (PMMA), polycarbonate, acrylonitrile styrene copolymer (AS resin), or polystyrene.

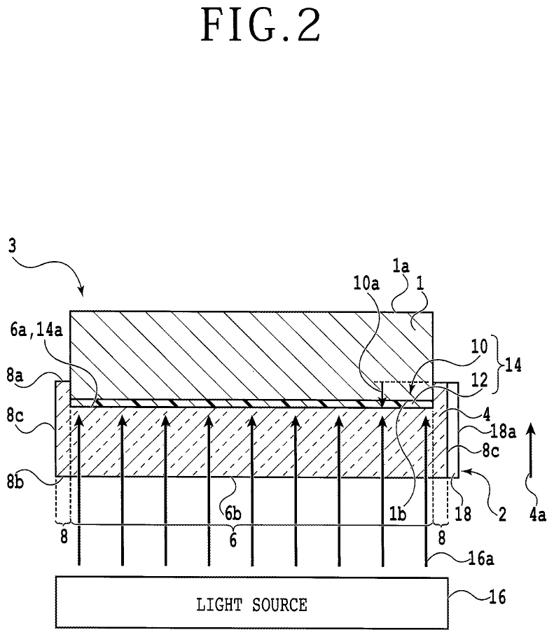

The base 4 has a disk-shaped central body 6 having an upper surface 6a and a lower surface 6b (see FIG. 2), each having a circular shape. The upper surface 6a and the lower surface 6b lie parallel to each other and are slightly larger in diameter than the ingot 1. According to the present embodiment, since the base 4 holds thereon the ingot 1 that has a diameter of approximately 150 mm (6 inches according to the SEMI standards), the upper surface 6a and the lower surface 6b have a diameter of approximately 151 mm. The central body 6 is solid throughout from the upper surface 6a to the lower surface 6b, though it may have a cavity therein.

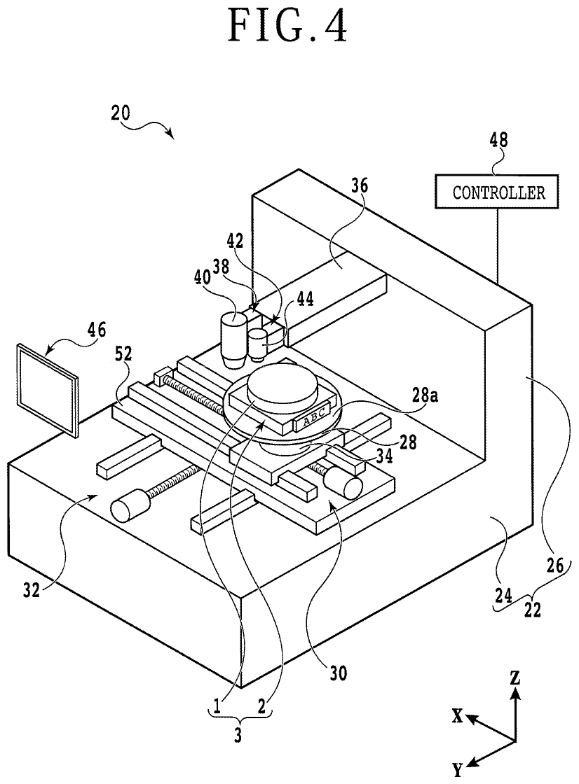

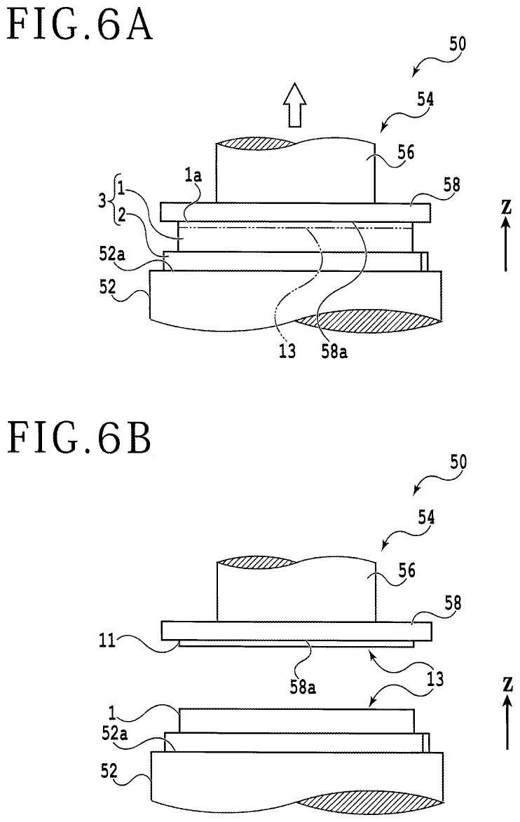

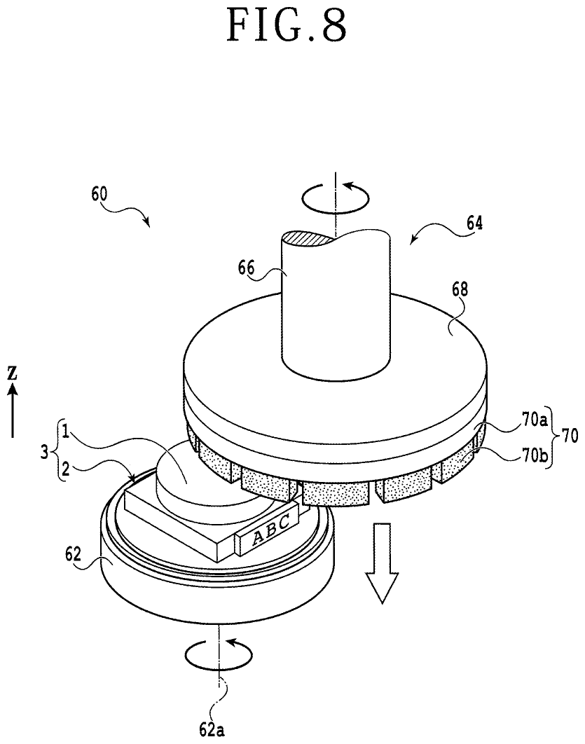

The central body 6 is surrounded by an outer circumferential body 8 having a contour as a rectangular plate. The outer circumferential body 8 shaped as a rectangular plate makes it easy to position the jig 2 with respect to a chuck table of a processing apparatus to be described later when the operator places the ingot unit 3 on the chuck table. However, if the operator does not place the jig 2 on the chuck table, but a processing apparatus such as a laser processing apparatus 20 (see FIG. 4), a peeling apparatus 50 (see FIGS. 6A and 6B), or a grinding apparatus 60 (see FIG. 8) to be described later automatically positions the jig 2, the outer circumferential body 8 may not be shaped as a rectangular plate, but as a disk.

The outer circumferential body 8 has an annular upper surface 8a and an annular lower surface 8b (see FIG. 2). The upper surface 8a has a circular inner circumferential edge and a square outer circumferential edge. A distance from the circular inner circumferential edge to the square outer circumferential edge ranges from approximately 5 mm to approximately 10 mm. The lower surface 8b lies flush with the lower surface 6b of the central body 6 and has a square outer circumferential edge.

The outer circumferential body 8 is thicker than the central body 6. According to the present embodiment, the thickness of the outer circumferential body 8 from the upper surface 8a to the lower surface 8b is of approximately 10 mm, and the upper surface 8a of the outer circumferential body 8 protrudes upwardly from the upper surface 6a of the central body 6 by approximately 0.1 mm. Because of the step between the upper surface 8a of the outer circumferential body 8 and the upper surface 6a of the central body 6, the base 4 has an upwardly open disk-shaped recess 10 defined therein that has a predetermined depth. The recess 10 is positioned remotely from the lower surfaces 6b and 8b along a thicknesswise direction 4a with respect to the base 4.

As illustrated in FIG. 2, the recess 10 accommodates therein a bottom portion of the ingot 1 that includes the bottom surface 1b. When the bottom portion of the ingot 1 is received in the recess 10, the ingot 1 protrudes upwardly from the base 4. FIG. 2 is a cross-sectional view taken along line A - A of FIG. 1B. FIG. 2 also illustrates a light source 16 to be described later. The recess 10 has a bottom surface provided as the upper surface 6a of the central body 6. An adhesive layer 12 having a predetermined thickness is disposed on the upper surface 6a of the central body 6 for holding the ingot 1 on the base 4. The adhesive layer 12 is made of an ultraviolet-curable resin. The adhesive layer 12 remains adhesive at normal temperature under normal pressure before it is irradiated with ultraviolet rays, and has its bonding power reduced when it is irradiated with ultraviolet rays through the central body 6.

According to the present embodiment, the recess 10 and the adhesive layer 12 jointly function as a holding mechanism 14 for holding the ingot 1, and the upper surface 6a of the central body 6, i.e., the bottom surface of the recess 10, functions as a holding surface 14a for holding the ingot 1 with the adhesive layer 12 interposed therebetween. When the bottom portion of the ingot 1 is placed in the recess 10 and the bottom surface 1b of the ingot 1 is secured in place by the holding surface 14a with the adhesive layer 12 interposed therebetween, the bottom surface 1b of the ingot 1 is protected from impacts applied while the ingot 1 held by the jig 2 is being delivered, ground, or otherwise processed, i.e., is less likely to be cracked, chipped, or damaged than if the bottom surface 1b would otherwise be kept in direct contact with the holding surface 14a. According to the present embodiment, the upper surface 6a of the central body 6, i.e., the holding surface 14a, has a diameter of approximately 151 mm, as described above. However, a base 4 having a holding surface 14a whose diameter is of an appropriate value depending on the diameter of an ingot 1 to be handled may be selected for holding the ingot 1.

In order to manufacture as many wafers 11 from the ingot 1 as possible, the recess 10 has a predetermined depth 10a smaller than the thickness of each of the wafers 11 to be manufactured from the ingot 1. According to the present embodiment, each wafer 11 has a thickness of 0.4 mm, and the depth 10a of the recess 10 is smaller than 0.4 mm. The depth 10a of the recess 10 is larger than the thickness of the adhesive layer 12. Inasmuch as the depth 10a of the recess 10 is larger than the thickness of the adhesive layer 12, i.e., the thickness of the adhesive layer 12 is smaller than the depth 10a of the recess 10, the bottom portion of the ingot 1 can be accommodated in the recess 10 despite the adhesive layer 12 disposed in the recess 10, i.e., on the upper surface 6a of the central body 6.

According to the present embodiment, the thickness of the adhesive layer 12 is of 0.01 mm, i.e., 10 μm, and the depth 10a of the recess 10 is of 0.1 mm. In view of the accuracy with which to machine the base 4, the depth 10a of the recess 10 should preferably be 0.1 mm or larger. For example, the depth 10a of the recess 10 should preferably be in a range from 0.1 mm to less than 0.4 mm. The depth 10a of the recess 10 in the above range makes it easy to position the ingot 1 in the recess 10 when the ingot 1 is to be secured to the holding mechanism 14 of the base 4. Furthermore, even when external forces tending to move the ingot 1 in directions along the upper surfaces 6a and 8a are applied to the ingot 1 while the ingot 1 is being processed in processing steps to be described later, the ingot 1 is restrained from moving by the recess 10 and hence is prevented from being displaced with respect to the base 4 and from being dislodged from the base 4.

As described above, the ingot 1 is secured to the base 4 with the adhesive layer 12 interposed therebetween. When ultraviolet rays 16a are applied from the light source 16 to the adhesive layer 12, as illustrated in FIG. 2, the bonding power of the adhesive layer 12 is lowered, allowing the ingot 1 to be removed from the base 4. According to the present embodiment, since the base 4 is made in its entirety from the bottom surface, i.e., the lower surfaces 6b and 8b, of the base 4 to the holding surface 14a and the upper surface 8a in the thicknesswise direction 4a with respect to the base 4, of a resin that is substantially transparent to the ultraviolet rays 16a, the ultraviolet rays 16a emitted from the light source 16 reach the holding surface 14a. As long as the central body 6 is made in its entirety from the lower surface 6b to the upper surface 6a of a resin that is substantially transparent to the ultraviolet rays 16a, the outer circumferential body 8 may not be substantially transparent to the ultraviolet rays 16a, i.e., may be made of a material such as metal, ceramic, or resin that is not transmissive of the ultraviolet rays 16a.

A plate, i.e., an information recording member, 18 is fixed by a fastener such as an adhesive or bolts (not depicted) to a side surface of the base 4, i.e., a side surface 8c of the outer circumferential body 8. The plate 18 is a small white board, for example. The operator can draw information that may be represented by one or more combined of colors, symbols, numerals, letters, figures, patterns, and pictures on a surface 18a of the plate 18, using a dedicated marker, specifically, a felt-tip pen that supplies, from its distal end, an ink made up of a mixture of a pigment, a resin, and a release agent dissolved in a solvent such as alcohol.

The operator draws individual information 1c (see FIG. 1A) of the ingot 1 that is made up of numerals, alphabetical letters, etc. on the surface 18a of the plate 18, so that the individual information 1c is indicated on the surface 18a of the plate 18. The individual information 1c of the ingot 1 is thus identifiably recorded on the plate 18. As the plate 18 is in the form of a white board, the individual information 1c can easily be written on or erased from the plate 18. While the letters “ABC” are drawn as the individual information 1c on the surface 18a of the plate 18 in FIGS. 1A and 1B, they are added by way of example only for illustrative purposes, and the individual information 1c is not limited to the illustrated example.

The plate 18 is not limited to a white board and may be a memo pad in the form of a rectangular sheet of paper or wood on which numerals or letters can be written using a writing instrument such as a pen, or an electronic or magnetic memo pad shaped as a rectangular plate on which numerals or letters can be written by a dedicated pen-type device. Information represented by one or more combined of colors, symbols, numerals, letters, figures, patterns, pictures, and two-dimensional codes may alternatively be indicated in advance on the surface 18a of the plate 18 by a process such as printing or engraving. Using such pre-indicated information on the plate 18 is effective to prevent the operator from writing individual information 1c in error. The individual information 1c may be corrected, altered, or updated by replacing the plate 18 with a new plate 18 or affixing a sheet, a seal, or a thin plate with corrected, altered, or updated individual information 1c written thereon to the surface 18a of the plate 18.

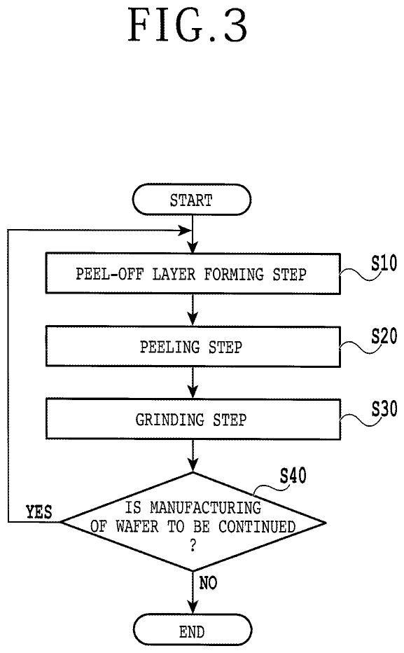

A method of manufacturing a plurality of wafers 11 will be described below with reference to FIGS. 3 through 9C. For the sake of brevity, a method of manufacturing a plurality of wafers 11 from a single ingot 1 will be described below. FIG. 3 is a flowchart of a method of manufacturing a plurality of wafers 11 from an ingot 1. For manufacturing a plurality of wafers 11, the ingot unit 3 including the ingot 1 and the jig 2 that are integrated with each other with the adhesive layer 12 interposed therebetween that is disposed in the recess 10 in the base 4 is used, as described above. The ingot 1 as it is integrated with the jig 2 is delivered and processed.

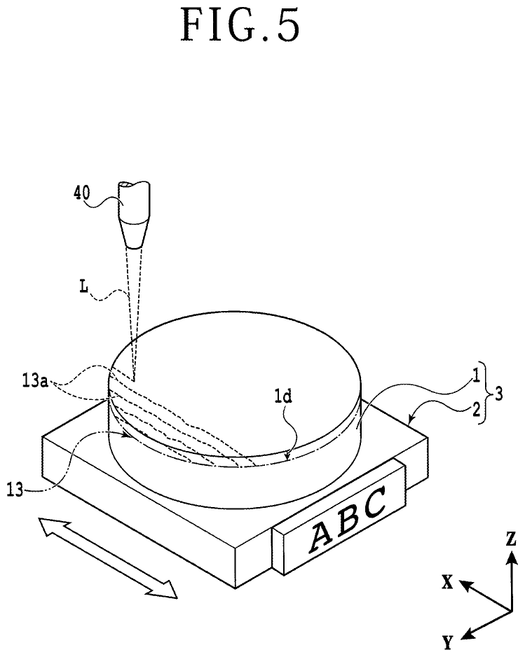

In the manufacturing process, the laser processing apparatus 20 (see FIG. 4) is used to form a peel-off layer 13 (see FIG. 5) in the ingot 1 (peel-off layer forming step S10, see FIG. 3) and then the peeling apparatus 50 (see FIGS. 6A and 6B) is used to peel off a wafer 11 from the ingot 1 along the peel-off layer 13 (peeling step S20). Thereafter, the grinding apparatus 60 (see FIG. 8) is used to grind the upper surface of the ingot 1 from which the wafer 11 has been peeled off (grinding step S30). If the manufacturing process for manufacturing another wafer 11 from the ingot 1 is to be continued (YES in step S40), then the processing sequence goes back to peel-off layer forming step S10. If the manufacturing process for manufacturing another wafer 11 from the ingot 1 is not to be continued (NO in step S40), then the processing sequence comes to an end.

FIG. 4 illustrates the laser processing apparatus 20 in perspective. As illustrated in FIG. 4, the laser processing apparatus 20 includes a base 22 that supports the components of the laser processing apparatus 20. The base 22 includes a horizontal portion 24 shaped as a flat plate and a vertical wall 26 positioned at a rear end of the horizontal portion 24 and extending upwardly from the horizontal portion 24. A disk-shaped chuck table 28 for holding an ingot unit 3 under suction thereon is disposed above the horizontal portion 24. The chuck table 28 is movable along an X-axis indicated by an arrow X and a Y-axis indicated by an arrow Y by a ball-screw-type X-axis moving unit 30 and a ball-screw-type Y-axis moving unit 32, respectively. The X-axis and the Y-axis extend horizontally perpendicularly to each other. The chuck table 28 is rotatable about its vertical central axis along a Z-axis indicated by an arrow Z by a rotating drive unit 34. The Z-axis extends vertically perpendicularly to the X-axis and the Y-axis.

The chuck table 28 has a holding surface 28a on which the ingot unit 3 is to be held. The holding surface 28a is made of a porous material and is fluidly connected to a suction source, not depicted, such as a vacuum pump. When the ingot unit 3 is placed on the holding surface 28a, the suction source is actuated to generate and transmit a vacuum to the holding surface 28a, which holds the jig 2 of the ingot unit 3 under suction thereon. A horizontal support arm 36 extends forwardly from an upper portion of a front surface of the vertical wall 26 in overhanging relation to the chuck table 28. The support arm 36 supports part of a laser beam applying unit 38 therein. The laser beam applying unit 38 includes a cylindrical head 40 mounted on a distal end of the support arm 36 and a laser oscillator, not depicted, fixed with respect to the base 22.

The laser oscillator has a crystal of a material such as Nd:YAG functioning as a laser medium, for example. The laser oscillator generates and emits a pulsed laser beam L (see FIG. 5) having a predetermined wavelength of 1064 nm, for example. The pulsed laser beam L is applied from the head 40 to the ingot 1 of the ingot unit 3 on the chuck table 28. A microscope camera unit 42 is supported on the distal end of the support arm 36 and includes a head 44 positioned adjacent to the head 40. The microscope camera unit 42 includes, for example, an objective lens, a focusing lens, a light source, and a solid-state image capturing unit, all not depicted.

The laser processing apparatus 20 has an outer housing, not depicted, having a front surface on which a touch panel 46 is mounted. The touch panel 46 functions as an input device for entering processing conditions and other data and a display device for displaying images captured by the microscope camera unit 42 and other images and information. The laser processing apparatus 20 further has a controller 48 for controlling operation of the X-axis moving unit 30, the Y-axis moving unit 32, the rotating drive unit 34, the laser beam applying unit 38, the microscope camera unit 42, the touch panel 46, and other components.

The controller 48 includes a computer including, for example, a processor typically represented as a central processing unit (CPU), a main storage device such as a dynamic random access memory (DRAM), a static random access memory (SRAM), or a read only memory (ROM), and an auxiliary storage device such as a flash memory, a hard disk drive, or a solid state drive. The auxiliary storage device stores software including predetermined programs. The controller 48 has its functions performed by operating the processor according to the software.

FIG. 5 illustrates peel-off layer forming step S10 in perspective. In peel-off layer forming step S10, the operator delivers an ingot unit 3 to the chuck table 28 and places the ingot unit 3 on the holding surface 28a. At this time, since the outer circumferential body 8 of the base 4 has the contour as a rectangular plate, the ingot 1 can easily be oriented with respect to the X-axis or the Y-axis of the laser processing apparatus 20. After the ingot unit 3 has been placed on the holding surface 28a, the bottom surface of the jig 2 of the ingot unit 3 is held under suction on the holding surface 28a by the vacuum transmitted from the suction source.

Then, using the microscope camera unit 42, an alignment is carried out to direct the crystal orientation of the ingot 1 substantially parallel to the X-axis. Thereafter, the head 40 of the laser beam applying unit 38 applies the pulsed laser beam L to the ingot 1 to form a peel-off layer 13 as peeling initiating points in the ingot 1 along which a wafer 11 will be peeled off from the ingot 1. Specifically, the laser beam L is applied to the ingot 1 while positioning its focused spot within the ingot 1 at a predetermined depth 1d that corresponds to the thickness of the wafer 11 to be peeled off, and the chuck table 28 is moved along the X-axis by the X-axis moving unit 30. The laser beam L thus applied forms a modified region 13a whose mechanical strength has been reduced, i.e., which has been made fragile, in the ingot 1 along the locus of the focused spot of the laser beam L.

After the modified region 13a has been formed, the chuck table 28 is moved a given index distance along the Y-axis by the Y-axis moving unit 32. Thereafter, the laser beam L is applied to the ingot 1 while positioning its focused spot within the ingot 1 at the depth 1d, and the chuck table 28 is moved along the X-axis by the X-axis moving unit 30. The laser beam L thus applied forms a next modified region 13a parallel to the previously formed modified region 13a in the ingot 1. Similarly, a plurality of modified regions 13a are formed in succession in the ingot 1. The modified regions 13a extend along the X-axis across the ingot 1. A plurality of cracks, not depicted, extend from each of the modified regions 13a substantially along the Y-axis. The modified regions 13a and the cracks extending therefrom jointly make up the peel-off layer 13 at the depth 1d in the ingot 1. After peel-off layer forming step S10, the operator delivers the ingot unit 3 in which the peel-off layer 13 has been formed to the peeling apparatus 50 that carries out peeling step S20.

FIG. 6A illustrates the peeling apparatus 50 in side-elevation, partly in cross section. As illustrated in FIG. 6A, the peeling apparatus 50 has a disk-shaped chuck table 52 having an upper surface as a holding surface 52a for holding the jig 2 of the ingot unit 3 under suction thereon. The peeling apparatus 50 further includes a peeling unit 54 disposed above the chuck table 52. The peeling unit 54 has a vertical cylindrical support rod 56 to which there are coupled a ball-screw-type lifting and lowering mechanism and a rotary actuator such as an electric motor, both not depicted. The support rod 56 has a lower end to which a disk-shaped suction head 58 is fixed. The suction head 58 has a lower surface functioning as a suction surface 58a that lies substantially parallel to the holding surface 52a of the chuck table 52. The holding surface 52a and the suction surface 58a respectively have porous surfaces fluidly connected to respective suction sources.

In peeling step S20, the bottom surface of the jig 2 is held under suction on the holding surface 52a of the chuck table 52, and the top surface 1a of the ingot 1 is held under suction by the suction surface 58a of the suction head 58. Then, external forces are applied to the ingot 1. Specifically, a wedge, not depicted, is driven into the side surface of the ingot 1 at the height of the peel-off layer 13 to apply the external forces to the ingot 1. Preferably, a wedge should be driven into noy only one point but also a plurality of points on the side surface of the ingot 1 in spaced positions around the circumference of the ingot 1. The applied external forces cause the cracks of the peel-off layer 13 to extend further substantially parallel to the top surface 1a at the depth 1d in the ingot 1. Instead of the wedge, ultrasonic waves, i.e., elastic oscillation waves in a frequency band in excess of 20 kHz, may be applied to the ingot 1 to apply the external forces to the ingot 1.

After the external forces have been applied to the ingot 1, the suction head 58 is lifted, peeling off a wafer 11 from the ingot 1 along the peel-off layer 13 as peeling initiating points. FIG. 6B illustrates peeling step S20 in side-elevation, partly in cross section. FIG. 7 illustrates, in perspective, the wafer 11 that has been peeled off from the ingot 1 in peeling step S20. After peeling step S20, since residuals such as chips, particulates, and powdery matter tend to exist on an exposed surface of the peel-off layer 13 as a newly formed top surface 1a of the ingot 1, the top surface 1a may be cleaned with pure water and then dried by a spinner cleaning apparatus, for example.

After peeling step S20, the operator delivers the ingot unit 3 from which the wafer 11 has been peeled off to the grinding apparatus 60 (see FIG. 8) that carries out grinding step S30. As illustrated in FIG. 8, the grinding apparatus 60 includes a disk-shaped chuck table 62 having a porous holding surface. The holding surface of the chuck table 62 is fluidly connected to a suction source. The chuck table 62 is rotatable about a vertical central axis 62a by a rotating drive unit, not depicted. The grinding apparatus 60 further includes a grinding unit 64 disposed above the chuck table 62. The grinding unit 64 is coupled to a ball-screw-type grinding feed mechanism, not depicted, for moving the grinding unit 64 along the Z-axis.

The grinding unit 64 has a vertical cylindrical spindle 66 having a lower end to which a central portion of an upper surface of a disk-shaped wheel mount 68 is fixed. The spindle 66 is rotatable about its vertical central axis by a rotating drive unit. The wheel mount 68 has a lower surface on which an annular grinding wheel 70 is mounted. The grinding wheel 70 has an annular base 70a made of a metal material such as aluminum alloy. The base 70a has an upper surface fixed to the lower surface of the wheel mount 68. The base 70a has a lower surface on which a plurality of grindstones 70b each shaped as a block are fixedly mounted at equal spaced intervals along the circumference of the base 70a.

FIG. 8 illustrates grinding step S30, in perspective. In grinding step S30, the bottom surface of the jig 2 of the ingot unit 3 is held under suction on the holding surface of the chuck table 62. Then, the chuck table 62 is rotated about the vertical central axis 62a by the rotating drive unit, and the grinding unit 64 is grinding-fed downwardly by the grinding feed mechanism while the spindle 66 is being rotated about its vertical central axis by the rotating drive unit. The grindstones 70b as they are rotated by the grinding unit 64 grind the exposed peel-off layer 13 as the top surface 1a of the ingot 1 in abrasive contact therewith, substantially planarizing the top surface 1a. The top surface 1a is ground by the grindstones 70b while pure water is being supplied to the grindstones 70b.

After a predetermined amount of material of the top surface 1a has been ground off, grinding step S30 is finished. If necessary, grinding step S30 may be followed by a polishing step for polishing the ground top surface 1a. After grinding step S30, if the manufacturing process for manufacturing another wafer 11 from the ingot 1 is to be continued (YES in step S40), then the processing sequence goes back to peel-off layer forming step S10. If the manufacturing process for manufacturing another wafer 11 from the ingot 1 is not to be continued (NO in step S40), then the processing sequence comes to an end.

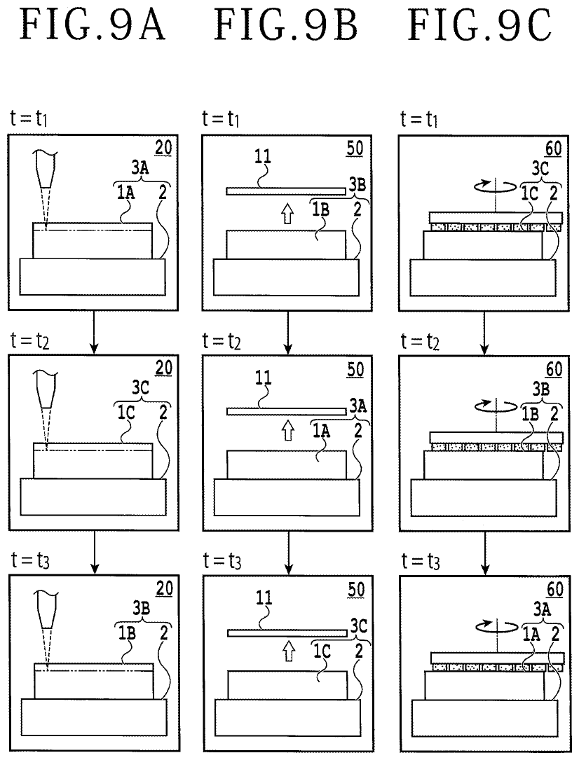

FIGS. 9A through 9C illustrate the manufacturing process that is carried out on a plurality of ingots 3. In FIGS. 9A through 9C, the movement and rotation of the ingot 1 and the jig 2 are omitted from illustration, and the components are illustrated in a simplified fashion with reference characters held to a minimum. FIG. 9A illustrates a time sequence of peel-off layer forming step S10 performed on the laser processing apparatus 20. FIG. 9B illustrates a time sequence of peeling step S20 performed on the peeling apparatus 50. FIG. 9C illustrates a time sequence of grinding step S30 performed on the grinding apparatus 60. Time t in FIGS. 9A through 9C indicates time t₁, time t₂, and time t₃ at different stages of the time sequence. The stage represented by time t₁ is earliest, the stage represented by time t₃ is latest, and the stage represented by time t₂ is intermediate between time t₁ and time t₃.

As illustrated in FIGS. 9A through 9C, initially, an ingot unit 3A is delivered to the laser processing apparatus 20, an ingot unit 3B in which a peel-off layer 13 has already been formed is delivered to the peeling apparatus 50, and an ingot unit 3C from which a wafer 11 has been peeled off is delivered to the grinding apparatus 60. At time t₁, the laser processing apparatus 20 performs peel-off layer forming step S10 on the ingot unit 3A, the peeling apparatus 50 performs peeling step S20 on the ingot unit 3B, and the grinding apparatus 60 performs grinding step S30 on the ingot unit 3C, concurrently with each other.

After time t₁, the ingot unit 3C after grinding step S30 is delivered to the laser processing apparatus 20, the ingot unit 3A after peel-off layer forming step S10 is delivered to the peeling apparatus 50, and the ingot unit 3B after peeling step S20 is delivered to the grinding apparatus 60. At time t₂, the laser processing apparatus 20 performs peel-off layer forming step S10 on the ingot unit 3C, the peeling apparatus 50 performs peeling step S20 on the ingot unit 3A, and the grinding apparatus 60 performs grinding step S30 on the ingot unit 3B, concurrently with each other.

After time t₂, the ingot unit 3B after grinding step S30 is delivered to the laser processing apparatus 20, the ingot unit 3C after peel-off layer forming step S10 is delivered to the peeling apparatus 50, and the ingot unit 3A after peeling step S20 is delivered to the grinding apparatus 60. At time t₃, the laser processing apparatus 20 performs peel-off layer forming step S10 on the ingot unit 3B, the peeling apparatus 50 performs peeling step S20 on the ingot unit 3C, and the grinding apparatus 60 performs grinding step S30 on the ingot unit 3A, concurrently with each other.

After time t₃, the ingot unit 3A after grinding step S30 is delivered again to the laser processing apparatus 20, the ingot unit 3B after peel-off layer forming step S10 is delivered again to the peeling apparatus 50, and the ingot unit 3C after peeling step S20 is delivered again to the grinding apparatus 60. In this manner, each of the ingot units 3A, 3B, and 3C is delivered successively to the laser processing apparatus 20, the peeling apparatus 50, and the grinding apparatus 60 to circulate therethrough such that peel-off layer forming step S10, peeling step S20, and grinding step S30 are successively performed on each of the ingot units 3A, 3B, and 3C. When the ingot units 3A, 3B, and 3C are thus cyclically processed by the laser processing apparatus 20, the peeling apparatus 50, and the grinding apparatus 60, a plurality of wafers 11 are manufactured from each of respective ingots 1A, 1B, and 1C of the ingot units 3A, 3B, and 3C. Since the individual information 1c of the ingots 1A, 1B, and 1C can be identified from the plates 18 on the jigs 2 of the ingot units 3A, 3B, and 3C, the ingots 1A, 1B, and 1C as they are delivered and processed are easily identified and managed individually for increased productivity for the wafers 11.

The plate 18 may bear not only the individual information 1c, but also the items (1) through (5) of information described below. If any of the information cannot be recorded in the form of numerals and characters on the surface 18a, then they may be recorded as a two-dimensional code.

(1) The thickness of wafers 11, the total number of wafers 11 manufactured from the ingot 1, the material loss of the ingot 1 caused when wafers 11 are manufactured from the ingot 1, the yield information, the days and times of the respective steps, the periods of times required by the respective steps, the information as to whether each step has been finished normally or abnormally, the name of the operator, and the production serial numbers of the apparatus used in the steps;

(2) The information with respect to peel-off layer forming step S10, i.e., the output power and frequency of the laser beam, the angle of the processing feed direction with respect to the notch or orientation flat, the number of passes, the processing feed speed, and the depth of the focused spot in the ingot 1;

(3) The information with respect to the printing of numerals and/or letters on the surface 18a, i.e., the output power and frequency of the laser beam used in the printing, the spacing between, the positions of, and the contents of the printed numerals and/or letters;

(4) The information with respect to peeling step S20, i.e., the negative pressures or vacuums applied to the peeling unit 54, the cleaning period, the drying period; and

(5) The information with respect to grinding step S30, i.e., the amount of material ground off, the processing feed speed, the rotational speed and rotating direction of the spindle 66, the rotational speed and rotating direction of the chuck table 62, the amount of material ground off the ingot 1 and the processing feed speed upon air cutting, the amount of material ground off the ingot 1 and the processing feed speed upon escape cutting, the amount of material worn off the grindstones 70b, the maximum load on the chuck table 62, and the maximum current value supplied to drive the spindle 66.

The information of a two-dimensional code can be read by a portable device equipped with a camera or a dedicated reader, both not depicted. The read information is managed by a host computer, not depicted, of a computer network in the factory where the apparatuses are installed, for example.

### Second Embodiment

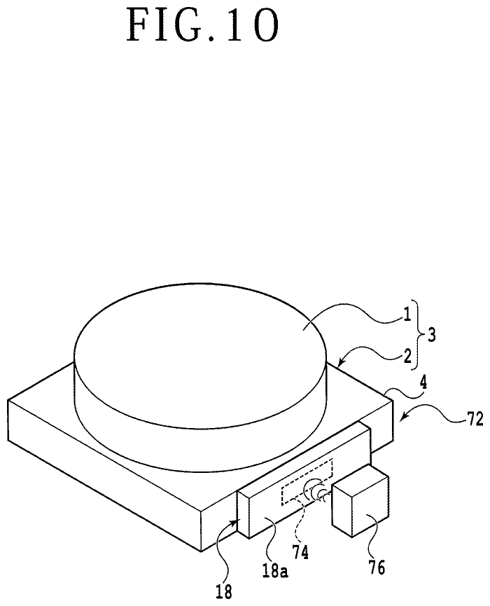

A second embodiment of the present invention will be described below with reference to FIG. 10 of the accompanying drawings. FIG. 10 illustrates, in perspective, an ingot unit 3 according to the second embodiment. As illustrated in FIG. 10, the ingot unit 3 includes a jig 72 having a plate, i.e., an information recording member, 18 that has an IC tag 74 disposed therein or on its surface 18a, rather than a white board. The IC tag 74 is also called a radio-frequency (RF) tag, a radio-frequency-identification (RFID) tag, or an electronic tag. The IC tag 74 may be of the passive type or the active type.

A reader writer 76 is used to read information from the IC tag 74 via wireless communication and also to write information into the IC tag 74 via wireless communication. The reader writer 76 may be associated with each of the laser processing apparatus 20, the peeling apparatus 50, and the grinding apparatus 60, and may be a portable device such as a smartphone. The IC tag 74 is capable of recording therein more information than the information indicated on the surface 18a, and of recording information with respect to the manufacture of wafers 11 in addition to the individual information 1c described above. The information with respect to the manufacture of wafers 11 includes the items (1), (2), (4), and (5) of information referred to above, for example.

The information read from the IC tag 74 by the reader writer 76 is managed by the host computer, not depicted, of the computer network in the factory where the apparatuses are installed, for example. The information recorded in the IC tag 74 with respect to the manufacture of wafers 11 can be updated through the reader writer 76 by an exchange of information between the IC tag 74 and the host computer.

Specifically, for example, after identification information has been sent from the IC tag 74 to the host computer through the reader writer 76, the host computer transmits processing conditions through the reader writer 76 to the IC tag 74, so that the processing conditions are recorded in the IC tag 74 by the reader writer 76. After the ingot 1 has been processed, the reader writer 76 records information with respect to the manufacture of wafers 11 in the IC tag 74, after which the reader writer 76 reads the same information recorded in the IC tag 74. The same information is thus transmitted together with the identification information to the host computer.

Therefore, the host computer can centrally manage the identification information of each ingot 1 and the information with respect to the manufacture of wafers 11 from each ingot 1. The central management of information is highly useful in tracking the information subsequently.

### Third Embodiment

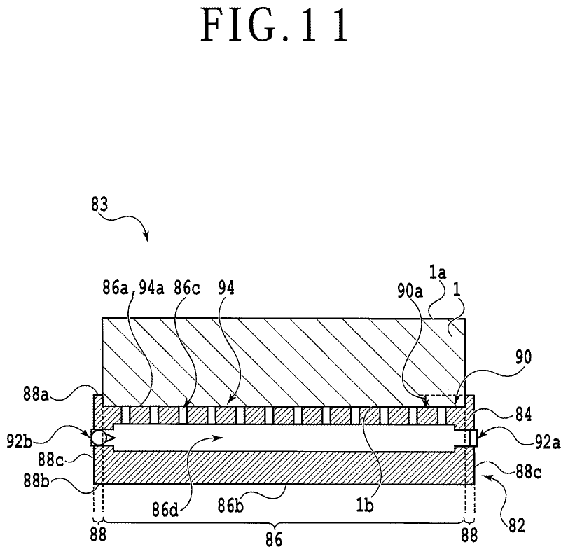

A third embodiment of the present invention will be described below with reference to FIG. 11 of the accompanying drawings. FIG. 11 illustrates an ingot unit 3 according to the third embodiment in side-elevation, partly in cross section. As illustrated in FIG. 11, the ingot unit 3 has a jig 82 including a base 84 and a plate 18 (not depicted in FIG. 11). The base 84 is substantially identical in shape to the base 4 according to the first and second embodiments. The base 84 is made of a metal material such as stainless steel or aluminum alloy, for example. The base 84 has a disk-shaped central body 86 and an outer circumferential body 88. The central body 86 has an upper surface 86a and a lower surface 86b, each having a circular shape.

The outer circumferential body 88 has a contour as a rectangular plate, though it may have a contour as an annular shape. The outer circumferential body 88 has an annular upper surface 88a and an annular lower surface 88b. The upper surface 88a has a circular inner circumferential edge and a square outer circumferential edge. The lower surface 88b of the outer circumferential body 88 lies substantially flush with the lower surface 86b of the central body 86. The outer circumferential body 88 is thicker than the central body 86. The upper surface 88a of the outer circumferential body 88 protrudes upwardly from the upper surface 86a of the central body 86.

Because of the step between the upper surface 88a of the outer circumferential body 88 and the upper surface 86a of the central body 86, the base 84 has an upwardly open disk-shaped recess 90 defined therein that has a predetermined depth 90a. The recess 90 receives therein a bottom portion of the ingot 1 that includes the bottom surface 1b thereof while at the same time the ingot 1 protrudes upwardly from the recess 90. The depth 90a of the recess 90 is smaller than the thickness of each of wafers 11 manufactured from the ingot 1. The bottom surface of the recess 90, i.e., the upper surface 86a of the central body 86, has a plurality of suction holes 86c defined vertically therethrough, with no adhesive layer 12 disposed on the bottom surface of the recess 90.

Each of the suction holes 86c is defined as a substantially cylindrical through hole held in fluid communication with a cavity 86d defined in the base 84. When the bottom portion of the ingot 1 is received in the recess 90, the suction holes 86c are covered with the bottom surface of the ingot 1. While the suction holes 86c are being covered with the bottom surface of the ingot 1, the cavity 86d is kept under an air pressure lower than the atmosphere in which the base 84 is disposed. A manually operable mechanical valve 92a is mounted in a portion of a side surface 88c of the base 84 for breaking a vacuum in the cavity 86d. A check valve 92b is mounted on a portion of the side surface 88c of the base 84 opposite the manually operable mechanical valve 92a across the base 84. In FIG. 11, the manually operable mechanical valve 92a and the check valve 92b are illustrated in a simplified manner.

For holding the ingot 1 on the upper surface 86a of the central body 86, i.e., the bottom surface of the recess 90, the ingot 1 is placed on the base 84 such that the bottom surface 1b of the ingot 1 is held in contact with the upper surface 86a. Thereafter, a suction source such as a vacuum pump, not depicted, is fluidly connected to the check valve 92b and actuated to evacuate the cavity 86d to create a vacuum in the cavity 86d. The upper surface 86a now functions as a holding surface 94a for holding the ingot 1 under suction thereon. According to the third embodiment, the upper surface 86a, the suction holes 86c, the cavity 86d, and the check valve 92a, etc. jointly function as a holding mechanism 94 that is different from the holding mechanism 14 according to the first embodiment.

When wafers 11 are manufactured from ingots 1, the ingot units 83 are delivered between the processing apparatuses several hundred times, e.g., 400 times. While the ingot units 83 are being delivered between the processing apparatuses, a vacuum leak is gradually in progress in each of the bases 84 of the jigs. Therefore, while the ingot units 83 are being delivered several hundred times and the ingots 1 are being processed on the processing apparatuses, the holding surface 94a of each of the bases 84 may possibly suffer a lack of enough holding power for holding the ingot 1 thereon. From the standpoint of maintaining a sufficient level of holding power, therefore, it is preferable to employ the holding mechanism 14 according to the first embodiment, rather than the holding mechanism 94 according to the third embodiment.

Nevertheless, the holding mechanism 94 according to the third embodiment is able to hold the ingot 1 securely for a certain period of time, and is advantageous in that it is free of any adhesive layer residues when the ingot 1 is removed from the base 84 because the holding mechanism 94 does not include the adhesive layer 12. The structural and processing details according to the embodiments of the present invention may be changed or modified without departing from the scope of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A jig for use in manufacturing a wafer from an ingot and for being delivered while being integrated with the ingot, comprising:
a base having a holding mechanism for holding the ingot such that the ingot protrudes therefrom; and
an information recording member fixed to the base for recording individual information of the ingot identifiably therein.

2. The jig according to claim 1, wherein the base has a disk-shaped recess defined therein that has a predetermined depth for accommodating a bottom portion of the ingot therein.

3. The jig according to claim 2, wherein
the base includes a central body capable of transmitting ultraviolet rays therethrough from a holding surface thereof as a bottom surface of the recess to a bottom surface of the base opposite the recess thicknesswise across the base,
the holding mechanism includes an adhesive layer disposed on the holding surface and made of an ultraviolet-curable resin having bonding power that is lowered when irradiated with ultraviolet rays, and
the ingot is held on the holding surface with the adhesive layer interposed therebetween before the adhesive layer is irradiated with ultraviolet rays.

4. The jig according to claim 3, wherein the adhesive layer disposed on the holding surface has a thickness smaller than the predetermined depth of the recess.

5. The jig according to claim 1, wherein the information recording member includes a plate capable of indicating on a surface thereof information represented by one or more combined of colors, symbols, numerals, letters, figures, patterns, pictures, and two-dimensional codes.

6. The jig according to claim 1, wherein the information recording member includes an integrated circuit tag for recording individual information that is read or written via wireless communication.

7. The jig according to claim 6, wherein the integrated circuit tag is capable of recording information with respect to manufacture of the wafer in addition to the individual information.

8. A method of manufacturing a plurality of wafers from each of a plurality of ingot units each including an ingot and a jig that are integrated with each other, the jig including a base having a holding mechanism for holding the ingot such that the ingot protrudes therefrom and an information recording member fixed to the base for recording individual information of the ingot identifiably therein, the method comprising:
a peel-off layer forming step of delivering an ingot unit to a laser processing apparatus and processing the ingot of the ingot unit with a laser beam on the laser processing apparatus to form a peel-off layer at a predetermined depth in the ingot as peeling initiating points along which a wafer is to be peeled off from the ingot;
a peeling step of delivering the ingot unit with the peel-off layer formed in the ingot to a peeling apparatus and peeling off the wafer from the ingot along the peel-off layer; and
a grinding step of delivering the ingot unit from which the wafer has been peeled off to a grinding apparatus and grinding an upper surface of the ingot of the ingot unit on the grinding apparatus, wherein
each of the ingot units is delivered successively to the laser processing apparatus, the peeling apparatus, and the grinding apparatus to circulate therethrough such that peel-off layer forming step, peeling step, and grinding step are successively performed on each of the ingot units, manufacturing a plurality of wafers from each of the respective ingots of the ingot units.
